(19) United States
(12) Patent Application Publication
(10) Pub. No.: US 2025/0284327 A1
(43) Pub. Date: Sep. 11, 2025

(54) ELECTRONIC DEVICE

(71) Applicant: Acer Incorporated, New Taipei City (TW)

(72) Inventors: Hui-Ping Sun, New Taipei City (TW); Chun-Hsien Chen, New Taipei City (TW); Jui-Yi Yu, New Taipei City (TW); Chun-Hung Wen, New Taipei City (TW); Yen-Chou Chueh, New Taipei City (TW)

(73) Assignee: Acer Incorporated, New Taipei City (TW)

(21) Appl. No.: 18/909,920

(22) Filed: Oct. 8, 2024

(30) Foreign Application Priority Data
Mar. 6, 2024 (TW) 113108031

(51) Int. Cl. G06F 1/20; H05K 7/20

(52) U.S. Cl. CPC G06F 1/203; H05K 7/20145

(57) ABSTRACT

Disclosed is an electronic device including a first body, a second body, and a movable door. The first body has a first pivot side and a heat dissipation opening located on the first pivot side, and the second body has a second pivot side pivoted to the first pivot side. An airflow channel is disposed on the second pivot side, corresponding to the heat dissipation opening. The movable door is rotatably disposed in the airflow channel. When the second body is folded on the first body, the movable door closes the airflow channel. When the second body is unfolded relative to the first body, the movable door rotates relative to the second body to open the airflow channel.

### CROSS-REFERENCE TO RELATED APPLICATION

This application claims the priority benefit of Taiwan application serial no. 113108031, filed on Mar. 6, 2024. The entirety of the above-mentioned patent application is hereby incorporated by reference herein and made a part of this specification.

### BACKGROUND

### Technical Field

The disclosure relates to an electronic device, and in particular to an electronic device with a heat dissipation design.

### Description of Related Art

Notebook computers have become a type of indispensable electronic devices at work or in daily life for modern people due to their portability, high computing performance, and other features. Specifically, a notebook computer consists of a first body and a second body that are pivoted to each other. The first body is a host capable of logical computing, and the second body is a monitor capable of image display.

The first body has internal heat sources, including a central processing unit, a graphics processing unit, or other electronic elements that generate a large amount of heat during operation. To quickly discharge the heat generated by the heat source from the inside of the first body to the external environment, an air-cooled heat dissipation module is usually disposed in the first body, corresponding to the heat source. Generally, an air-cooled heat dissipation module includes a fan, a heat pipe, and a heat sink. The fan mostly blows airflow to the rear side of the first body so that hot air is discharged to the external environment through the heat dissipation opening on the rear side of the first body. However, when the second body is unfolded relative to the first body, a lower edge of the second body easily blocks the discharge path of the hot air, causing the hot air to flow to a top surface of the first body (e.g., a surface where a keyboard set and a touch module are disposed) or a display surface of the second body. This results in an increase in the surface temperature of the first body or the second body and even affects the user experience in operation.

### SUMMARY

The disclosure provides an electronic device, which is capable of improving hot air reflux.

In an embodiment of the disclosure, an electronic device including a first body, a second body, a first magnetic member, and a movable door is provided. The first body has a first pivot side and a heat dissipation opening located on the first pivot side. The first magnetic member is disposed in the first body, corresponding to the first pivot side. The second body has a second pivot side pivoted to the first pivot side. An airflow channel is disposed on the second pivot side, corresponding to the heat dissipation opening. The movable door is rotatably disposed in the airflow channel. A second magnetic member is disposed corresponding to the first magnetic member. When the second body is folded on the first body, a magnetic attraction force generated between the second magnetic member and the first magnetic member fixes the movable door, enabling the movable door to close the airflow channel. When the second body is unfolded relative to the first body, the magnetic attraction force generated between the second magnetic member and the first magnetic member weakens, enabling the movable door to rotate relative to the second body by gravity to open the airflow channel.

In another embodiment of the disclosure, an electronic device including a first body, a second body, a first magnetic member, a movable door, and a torsion spring is provided. The first body has a first pivot side and a heat dissipation opening located on the first pivot side. The first magnetic member is disposed in the first body, corresponding to the first pivot side. The second body has a second pivot side pivoted to the first pivot side. An airflow channel is disposed on the second pivot side, corresponding to the heat dissipation opening. The movable door is rotatably disposed in the airflow channel. A second magnetic member is disposed on the movable door, corresponding to the first magnetic member. The torsion spring is connected between the movable door and the second body. When the second body is folded on the first body, a magnetic attraction force generated between the second magnetic member and the first magnetic member is greater than an elastic restoring force of the compressed torsion spring, thereby fixing the movable door and enabling the movable door to close the airflow channel. When the second body is unfolded relative to the first body, the magnetic attraction force generated between the second magnetic member and the first magnetic member is smaller than the elastic restoring force of the compressed torsion spring, enabling the movable door to be driven by the torsion spring and rotate relative to the second body to open the airflow channel.

In still another embodiment of the disclosure, an electronic device including a first body, a second body, and a movable door is provided. The first body has a first pivot side and a heat dissipation opening located on the first pivot side, and the second body has a second pivot side pivoted to the first pivot side. An airflow channel is disposed on the second pivot side, corresponding to the heat dissipation opening. The movable door is rotatably disposed in the airflow channel. When the second body is folded on the first body, the movable door closes the airflow channel. When the second body is unfolded relative to the first body, the movable door rotates relative to the second body to open the airflow channel.

Based on the above, in the electronic device of the disclosure, when the second body is unfolded relative to the first body, the movable door on the second pivot side of the second body may rotate to open the airflow channel, enabling the hot air in the first body to be discharged through the heat dissipation opening and further flows through the airflow channel to be discharged to an external environment. This prevents the hot air from being blocked by the second body and thus flowing to a top surface of the first body (e.g., a surface where a keyboard set and a touch module are disposed) or a display surface of the second body, which significantly improves hot air reflux.

To make the aforementioned features and advantages of the disclosure more comprehensible, several embodiments accompanied with drawings are described in detail as follows.

### BRIEF DESCRIPTION OF THE DRAWINGS

FIG. 1 is a schematic diagram of an electronic device in a first state in an embodiment of the disclosure.

FIG. 2 is a schematic diagram of the electronic device in FIG. 1 transitioning to a second state.

FIG. 3 is a schematic diagram of FIG. 2 in another view.

FIG. 4 is a partially enlarged schematic diagram of a region R1 in FIG. 1.

FIG. 5 is a partially enlarged schematic diagram of a region R2 in FIG. 2.

FIG. 6 is a partially enlarged schematic diagram of a region R3 in FIG. 3.

FIG. 7 is a partial cross-sectional schematic diagram of FIG. 4 along a section line A-A.

FIG. 8 is a partial cross-sectional schematic diagram of FIG. 7 transitioned to the second state.

### DESCRIPTION OF THE EMBODIMENTS

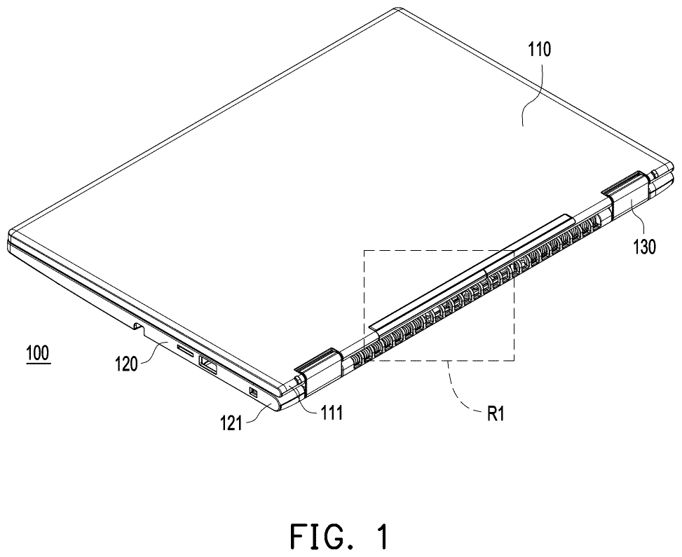

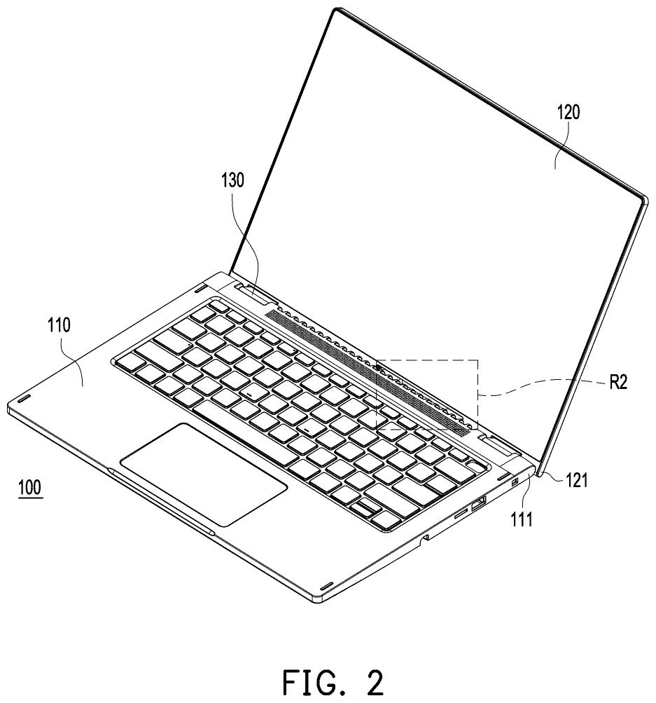

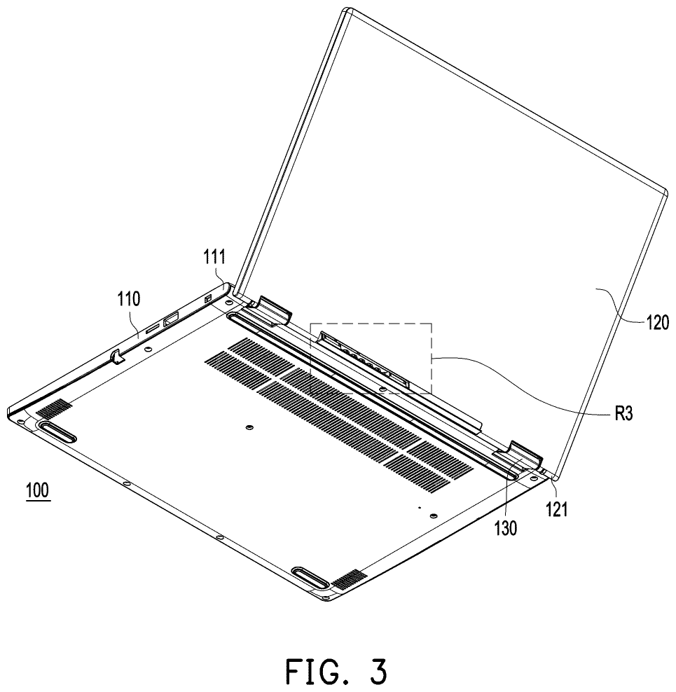

FIG. 1 is a schematic diagram of an electronic device in a first state in an embodiment of the disclosure. FIG. 2 is a schematic diagram of the electronic device in FIG. 1 transitioning to a second state. FIG. 3 is a schematic diagram of FIG. 2 in another view. Referring to FIGS. 1 to 3, in this embodiment, an electronic device 100 may be a notebook computer and includes a first body 110 and a second body 120 pivoted to each other. The first body 110 is a host capable of logical computing, and the second body 120 is a monitor capable of image display.

The second body 120 is pivoted to the first body 110 by a hinge structure 130 to be folded on or unfolded relative to the first body 110, for example, switching between a folded state (i.e., a first state) and an unfolded state (i.e., a second state). Further, the first body 110 has a first pivot side 111, wherein the second body 120 has a second pivot side 121 pivoted to the first pivot side 111, and the hinge structure 130 is connected between the second pivot side 121 and the first pivot side 111.

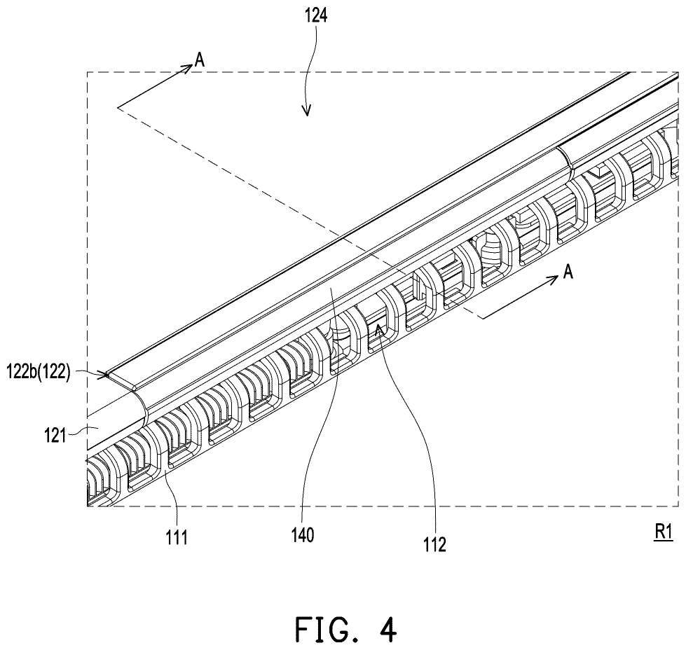

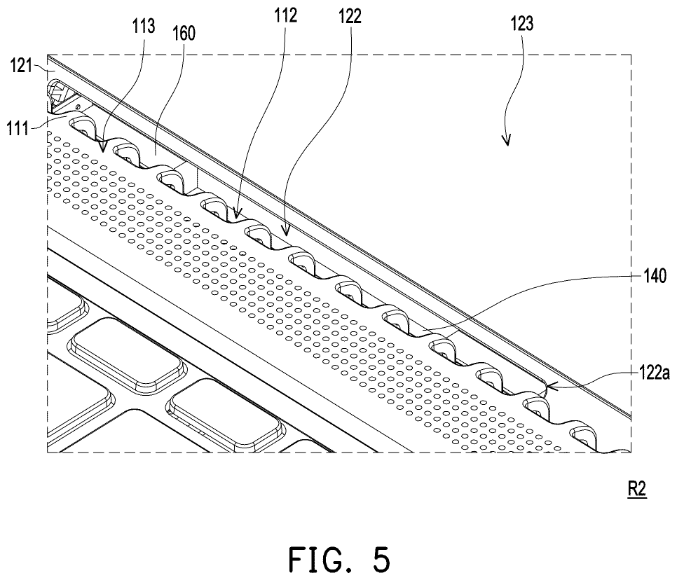

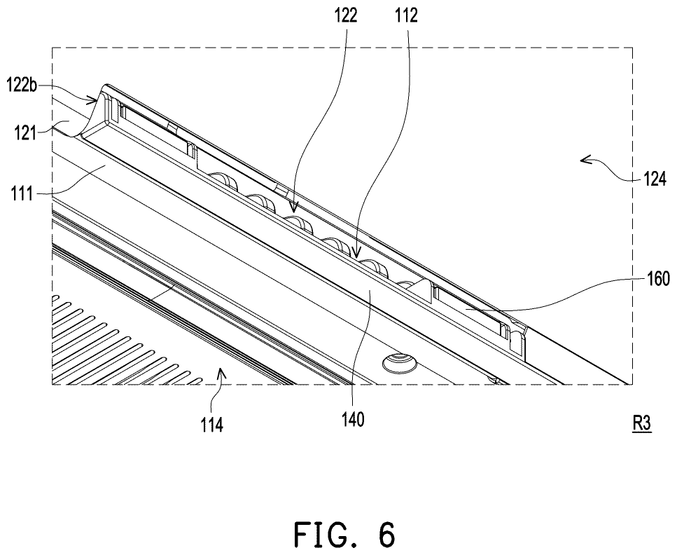

FIG. 4 is a partially enlarged schematic diagram of a region R1 in FIG. 1. FIG. 5 is a partially enlarged schematic diagram of a region R2 in FIG. 2. FIG. 6 is a partially enlarged schematic diagram of a region R3 in FIG. 3. Referring to FIGS. 1 and 4, in this embodiment, the first body 110 also has a heat dissipation opening 112 located on the first pivot side 111. An airflow channel 122 is disposed on the second pivot side 121, corresponding to the heat dissipation opening 112. Specifically, the electronic device 100 further includes a movable door 140, wherein the movable door 140 is pivoted to the second pivot side 121 and rotatably disposed in the airflow channel 122.

In the first state, the second body 120 is folded on the first body 110, and the entire movable door 140 is accommodated in the airflow channel 122 to close the airflow channel 122, as shown in FIGS. 1 and 4. In the second state, the second body 120 is unfolded relative to the first body 110, and at least a part of the movable door 140 moves out of the airflow channel 122 to open the airflow channel 122, as shown in FIGS. 2 and 5 or FIGS. 3 and 6.

For example, the airflow channel 122 is a groove located on the second pivot side 121, and the entire movable door 140 is adaptable to be accommodated in the groove. As the second body 120 is unfolded relative to the first body 110, the movable door 140 rotates relative to the second pivot side 121, enabling at least a part of the movable door 140 to move out of the groove.

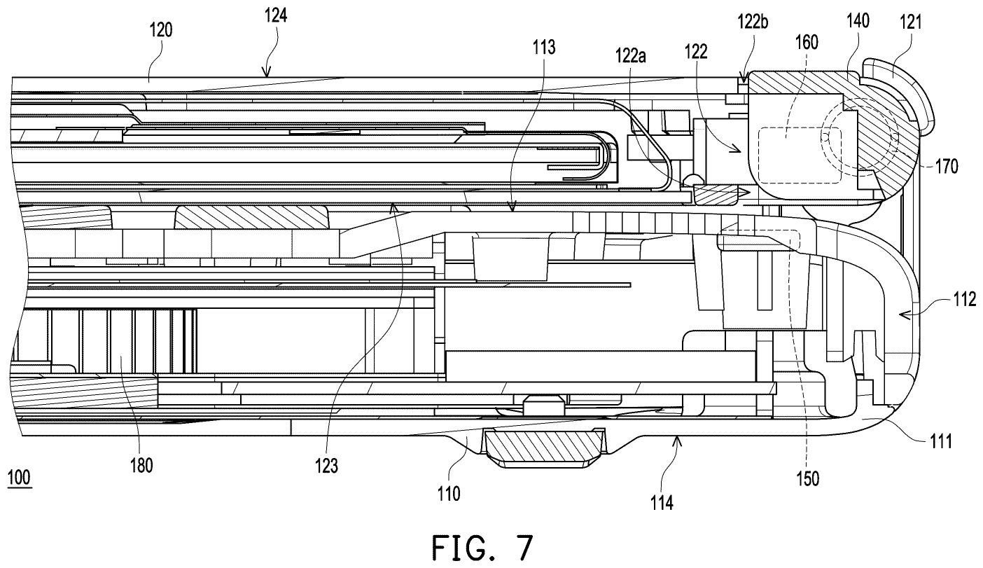

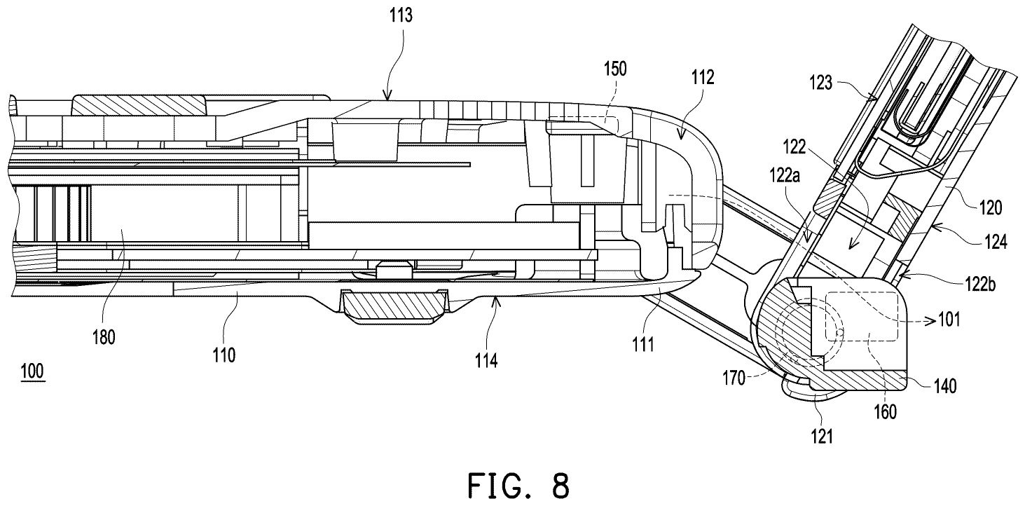

FIG. 7 is a partial cross-sectional schematic diagram of FIG. 4 along a section line A-A. FIG. 8 is a partial cross-sectional schematic diagram of FIG. 7 transitioned to the second state. Referring to FIGS. 4 to 7, the second body 120 has a display surface 123 and a back surface 124 relative to the display surface 123. The airflow channel 122 penetrates the display surface 123 and the back surface 124 to form an air inlet opening 122a and an air exhaust opening 122b on the display surface 123 and the back surface 124, respectively. On the other hand, the first body 110 has a top surface 113 and a bottom surface 114 relative to the top surface 113. In the first state, the second body 120 is folded on the first body 110, wherein the display surface 123 is bonded to the top surface 113, and the entire movable door 140 is accommodated in the airflow channel 122 to close the air inlet opening 122a and the air exhaust opening 122b.

As shown in FIGS. 5, 6, and 8, in the second state, the second body 120 is unfolded relative to the first body 110. The movable door 140 rotates relative to the second pivot side 121, enabling at least a part of the movable door 140 to move out of the airflow channel 122 through the air exhaust opening 122b to open the air inlet opening 122a and the air exhaust opening 122b.

Opening the airflow channel 122 or opening the air inlet opening 122a and the air exhaust opening 122b as previously mentioned refers to that the airflow is not blocked by the movable door 140 and flows to the air exhaust opening 122b through the airflow channel 122 or from the air inlet opening 122a. Relatively, closing the airflow channel 122 or closing the air inlet opening 122a and the air exhaust opening 122b as previously mentioned refers to that the airflow is blocked by the movable door 140 and unable to flow to the air exhaust opening 122b through the airflow channel 122 or from the air inlet opening 122a.

As shown in FIGS. 7 and 8, in an embodiment, the movable door 140 may be used to close the airflow channel 122 or open the airflow channel 122 by the gravity of the movable door 140. When the second body 120 is folded on the first body 110, the display surface 123 is bonded to the top surface 113, and the movable door 140 gets close to the top surface 113 by the gravity of the movable door 140 to close the airflow channel 122.

When the second body 120 is unfolded relative to the first body 110, the display surface 123 separates from the top surface 113, and the movable door 140 rotates relative to the second pivot side 121 by the gravity of the movable door 140, enabling at least a part of the movable door 140 to move out of the airflow channel 122 through the air exhaust opening 122b to open the airflow channel 122.

As shown in FIGS. 7 and 8, in another embodiment, the electronic device 100 further includes a first magnetic member 150, wherein the first magnetic member 150 is disposed in the first body 110, corresponding to the first pivot side 111. A second magnetic member 160 is disposed on the movable door 140, corresponding to the first magnetic member 150. Specifically, the first magnetic member 150 and the second magnetic member 160 may be two magnets or a combination of a magnet and an attracted body, which are adaptable to generate a magnetic attraction force between each other. When the second body 120 is folded on the first body 110, the magnetic attraction force generated between the second magnetic member 160 and the first magnetic member 150 fixes the movable door 140, enabling the movable door 140 to close the airflow channel 122 to prevent the movable door 140 from accidentally moving out of the airflow channel 122.

When the second body 120 is unfolded relative to the first body 110, the distance between the second magnetic member 160 and the first magnetic member 150 increases as the second body 120 is unfolded relative to the first body 110, enabling the magnetic attraction force generated between the second magnetic member 160 and the first magnetic member 150 to weaken. When the magnetic attraction force generated between the second magnetic member 160 and the first magnetic member 150 weakens and becomes smaller than the gravity of the movable door 140, the movable door 140 rotates relative to the second pivot side 121 by the gravity of the movable door 140, enabling at least a part of the movable door 140 to move out of the airflow channel 122 through the air exhaust opening 122b to open the airflow channel 122.

As shown in FIGS. 7 and 8, in still another embodiment, the electronic device 100 further includes a torsion spring 170 connected between the movable door 140 and the second body 120. When the second body 120 is folded on the first body 110, the magnetic attraction force generated between the second magnetic member 160 and the first magnetic member 150 fixes the movable door 140, enabling the movable door 140 to close the airflow channel 122 to prevent the movable door 140 from accidentally moving out of the airflow channel 122. Further, in a state where the movable door 140 closes the airflow channel 122, the torsion spring 170 is compressed by the movable door 140 and the elastic restoring force of the torsion spring 170 is smaller than the magnetic attraction force generated between the second magnetic member 160 and the first magnetic member 150, enabling the movable door 140 to be fixed in the airflow channel 122 by the magnetic attraction force generated between the second magnetic member 160 and the first magnetic member 150.

When the second body 120 is unfolded relative to the first body 110, the distance between the second magnetic member 160 and the first magnetic member 150 increases as the second body 120 is unfolded relative to the first body 110, enabling the magnetic attraction force generated between the second magnetic member 160 and the first magnetic member 150 to weaken. When the magnetic attraction force generated between the second magnetic member 160 and the first magnetic member 150 weakens and becomes smaller than the elastic restoring force of the torsion spring 170, the movable door 140 is driven by the torsion spring 170 and rotates relative to the second pivot side 121 by the gravity of the movable door 140, enabling at least a part of the movable door 140 to move out of the airflow channel 122 through the air exhaust opening 122b to open the airflow channel 122.

As shown in FIGS. 7 and 8, in this embodiment, the first magnetic member 150 is adjacent to the top surface 113. That is, the distance between the first magnetic member 150 and the top surface 113 is smaller than the distance between the first magnetic member 150 and the bottom surface 114. On the other hand, the electronic device 100 further includes a fan 180 disposed in the first body 110, wherein the first magnetic member 150 is located between the fan 180 and the heat dissipation opening 112. Moreover, the fan 180 may be a centrifugal fan for blowing cool air toward the heat dissipation opening 112.

As shown in FIG. 8, a hot air 101 in the first body 110 is adapted to flow toward the heat dissipation opening 112 and be discharged through the heat dissipation opening 112. In the second state, the airflow channel 122 is opened, enabling the hot air 101 to further flow through the airflow channel 122 to be discharged to the external environment after being discharged through the heat dissipation opening 112. This prevents the hot air 101 from being blocked by the second body 120 and thus flowing to the top surface 113 of the first body 110 (e.g., a surface where a keyboard set and a touch module are disposed) or the display surface 123 of the second body 120, which significantly improves the reflux of the hot air 101. With the reflux of the hot air 101 being improved, the surface temperature of the first body 110 or the second body 120 is less likely to increase under the impact of the hot air 101, thereby optimizing the user experience in operation.

As shown in FIG. 8, in the second state, the hot air 101 may be further blown toward the air inlet opening 122a after being discharged through the heat dissipation opening 112. Then, the hot air 101 may flow from the air inlet opening 122a to the air exhaust opening 122b to be discharged to the external environment, for example, to the surrounding area on a rear side 124 of the second body 120, through the air exhaust opening 122b.

In summary, in the electronic device of the disclosure, when the second body is unfolded relative to the first body, the movable door on the second pivot side of the second body may rotate to open the airflow channel, enabling the hot air in the first body to be discharged through the heat dissipation opening and further flows through the airflow channel to be discharged to an external environment. This prevents the hot air from being blocked by the second body and thus flowing to the top surface of the first body (e.g., the surface where the keyboard set and the touch module are disposed) or the display surface of the second body, which significantly improves hot air reflux. With hot air reflux being improved, the surface temperature of the first body or the second body is less likely to increase under the impact of hot air, thereby optimizing the user experience in operation.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. An electronic device, comprising:
a first body, having a first pivot side and a heat dissipation opening located on the first pivot side;
a second body, having a second pivot side pivoted to the first pivot side, wherein an airflow channel is disposed on the second pivot side, the airflow channel corresponding to the heat dissipation opening;
a first magnetic member, corresponding to the first pivot side and disposed in the first body; and
a movable door, rotatably disposed in the airflow channel, wherein a second magnetic member is disposed corresponding to the first magnetic member,
when the second body is folded on the first body, a magnetic attraction force generated between the second magnetic member and the first magnetic member fixes the movable door, enabling the movable door to close the airflow channel, and
when the second body is unfolded relative to the first body, the magnetic attraction force generated between the second magnetic member and the first magnetic member weakens, enabling the movable door to rotate relative to the second body by gravity to open the airflow channel.

2. The electronic device of claim 1, wherein a distance between the second magnetic member and the first magnetic member increases as the second body is unfolded relative to the first body.

3. The electronic device of claim 1, wherein the first body has a top surface and a bottom surface relative to the top surface, and the first magnetic member is adjacent to the top surface.

4. The electronic device of claim 1, further comprising a fan disposed in the first body, wherein the first magnetic member is located between the fan and the heat dissipation opening.

5. The electronic device of claim 1, wherein the airflow channel is a groove located on the second pivot side, and the entire movable door is adaptable to be accommodated in the groove, wherein at least a part of the movable door moves out of the groove as the second body is unfolded relative to the first body.

6. The electronic device of claim 1, wherein the second body has a display surface and a back surface relative to the display surface, and the airflow channel penetrates the display surface and the back surface.

7. The electronic device of claim 6, wherein the airflow channel has an air inlet opening located on the display surface and an air exhaust opening located on the back surface, wherein hot air in the first body is adaptable to be discharged through the heat dissipation opening and blown to the air inlet opening, and then flowing from the air inlet opening to the air exhaust opening to be discharged to an external environment through the air exhaust opening.

8. The electronic device of claim 6, wherein the airflow channel has an air inlet opening located on the display surface and an air exhaust opening located on the back surface, wherein at least a part of the movable door is adaptable to move out of the airflow channel through the air exhaust opening.

9. An electronic device, comprising:
a first body, having a first pivot side and a heat dissipation opening located on the first pivot side;
a second body, having a second pivot side pivoted to the first pivot side, wherein an airflow channel is disposed on the second pivot side, the airflow channel corresponding to the heat dissipation opening;
a first magnetic member, corresponding to the first pivot side and disposed in the first body;
a movable door, rotatably disposed in the airflow channel, wherein a second magnetic member is disposed corresponding to the first magnetic member; and
a torsion spring, connected between the movable door and the second body,
when the second body is folded on the first body, a magnetic attraction force generated between the second magnetic member and the first magnetic member is greater than an elastic restoring force of the compressed torsion spring, thereby fixing the movable door and enabling the movable door to close the airflow channel, and
when the second body is unfolded relative to the first body, the magnetic attraction force generated between the second magnetic member and the first magnetic member is smaller than the elastic restoring force of the torsion spring, enabling the movable door to be driven by the torsion spring and rotate relative to the second body to open the airflow channel.

10. An electronic device, comprising:
a first body, having a first pivot side and a heat dissipation opening located on the first pivot side;
a second body, having a second pivot side pivoted to the first pivot side, wherein an airflow channel is disposed on the second pivot side, the airflow channel corresponding to the heat dissipation opening; and
a movable door, rotatably disposed in the airflow channel,
when the second body is folded on the first body, the movable door closes the airflow channel, and
when the second body is unfolded relative to the first body, the movable door rotates relative to the second body to open the airflow channel.
